(19) United States
(12) Patent Application Publication
(10) Pub. No.: US 2021/0157508 A1
(43) Pub. Date: May 27, 2021

(54) TEST METHOD, SYSTEM, MEDIUM AND DEVICE FOR DUAL IN-LINE MEMORY MODULE

(71) Applicants: Inventec (Pudong) Technology Corporation, Shanghai (CN); INVENTEC CORPORATION, Taipei (TW)

(72) Inventors: Lin HOU, Tianjin (CN); Wei HUANG, Shanghai (CN)

(73) Assignees: Inventec (Pudong) Technology Corporation, Shanghai (CN); INVENTEC CORPORATION, Taipei (TW)

(21) Appl. No.: 17/095,764

(22) Filed: Nov. 12, 2020

(30) Foreign Application Priority Data
Nov. 26, 2019 (CN) 2019111740271

(51) Int. Cl. G06F 3/06

(52) U.S. Cl. CPC G06F 3/0653; G06F 3/0673; G06F 3/0604; G06F 3/062

(57) ABSTRACT

The present disclosure provides a test method, system, medium and device for a dual in-line memory module, the test method includes: obtaining a position of the dual in-line memory module on a server; modifying a protection mechanism after detecting a defective dual in-line memory module; testing each dual in-line memory module; storing the test result in a system event log of the baseboard management control module. The test method, system, medium and device for a dual in-line memory module of the present disclosure is to prevent the server from being shut down during the test of the dual in-line memory module, and timely discover the defective dual in-line memory module.

### CROSS REFERENCE TO RELATED APPLICATION

This application claims the benefits of priority to Chinese Patent Application No. CN 2019111740271, entitled “Test Method, System, Medium and Device for Dual In-Line Memory Module”, filed with CNIPA on Nov. 26, 2019, the contents of which are incorporated herein by reference in its entirety.

### BACKGROUND

### Field of Disclosure

The present disclosure relates to the field of dual in-line memory module testing technology, in particular, to a test method, system, medium and device for a dual in-line memory module.

### Description of Related Arts

The dual in-line memory module (DIMM) refers to a series of modules composed of dynamic random access memories (DRAM), which is currently the most mainstream type of memory. DIMM is widely used in personal computers, workstations and servers. DIMM is very important for server stability. DIMM would be strictly tested by the server manufacturers during the production of servers . Before the shipment, the server machine would be subjected to dozens of hours of stress testing, testing all parts of the server, in the hope of finding the parts of poor quality, including DIMM. During the device maintenance process, the server administrator would also conduct corresponding tests on DIMMs, hoping to find problems in the testing process, so as to timely replace the defective DIMMs. The entire testing process consumes a lot of time and power.

The basic input output system (BIOS) is a firmware that runs the hardware initialization during the power-on boot phase and provides runtime services for the operating system and program. BIOS is responsible for hardware startup and detection at boot time, and acts as an intermediary role when the operating system controls the hardware. The DIMM test in the BIOS is one of the functional modules in the Intel memory reference code (MRC). DIMM test module can find memory with error checking and correction (ECC) errors during BIOS boot. Intel's built-in advanced memory test can only collect logs through the serial port, and if a defective DIMM is found, the computer would be forced to be shut down. Therefore, the BIOS's built-in DIMM test program cannot be used on a large scale in a factory or data center.

Therefore, it is hoped to solve the problem of how to prevent the server from being shut down during the test of the dual in-line memory module, which causes a failure to the normal test.

### SUMMARY

The present disclosure provides a test method, system, medium and device for a dual in-line memory module, to solve the problem of how to prevent the server from being shut down during the test of the dual in-line memory module, which causes a failure to the normal test.

The present disclosure provides a test method for a dual in-line memory module, including: obtaining a position of the dual in-line memory module on a server; modifying a protection mechanism after detecting a defective dual in-line memory module, the modification of the protection mechanism after detecting the defective dual in-line memory module includes: prohibiting the function of shutting down the server after detecting the defective dual in-line memory module; prohibiting the function that the memory reference code shuts down the server after detecting the defective dual in-line memory module; prohibiting the function that the basic input output module gets stuck in a loop after detecting the defective dual in-line memory module; testing each dual in-line memory module; storing the test result in a system event log of the baseboard management control module.

In an embodiment of the present disclosure, the method further includes obtaining the test result stored in the system event log through a preset script.

In an embodiment of the present disclosure, the preset script is an IMPI platform management tool.

In an embodiment of the present disclosure, the method further includes cleaning the system event log and burning the basic input output module.

The present disclosure further provides a dual in-line memory module system, including a position acquisition unit, a modification unit, a test unit, and a storage unit;

The position acquisition unit obtains the position of the dual in-line memory module on the server.

The modification unit modifies a protection mechanism after detecting a defective dual in-line memory module, the modification of the protection mechanism after detecting the defective dual in-line memory module includes: prohibiting the function of shutting down the server after detecting the defective dual in-line memory module; prohibiting the function that the memory reference code shuts down the server after detecting the defective dual in-line memory module; prohibiting the function that the basic input output module gets stuck in a loop after detecting the defective dual in-line memory module; the test unit tests each dual in-line memory module; the storage unit stores the test result in a system event log of the baseboard management control module.

In an embodiment of the present disclosure, the system further includes a result acquisition unit to obtain the test result stored in the system event log through a preset script.

In an embodiment of the present disclosure, the preset script is an IMPI platform management tool.

In an embodiment of the present disclosure, the system further includes a cleaning unit to clean the system event log and burn the basic input output module.

The present disclosure provides a test device for a dual in-line memory module, including: a processor and a memory; the memory is configured to store a computer program, and the processor is connected with the memory to execute the computer program stored in the memory, so that the test device for a dual in-line memory module implements any of the test methods for a dual in-line memory module described above.

As described above, the test method, system, medium and device for a dual in-line memory module of the present disclosure has the following beneficial effects: preventing the server from being shut down during the test of the dual in-line memory module, timely discovering the defective dual in-line memory module.

### BRIEF DESCRIPTION OF THE DRAWINGS

FIG. 1 is a flowchart of a test method for a dual in-line memory module in an embodiment of the present disclosure.

FIG. 2 is a schematic diagram of a system for a dual in-line memory module in an embodiment of the present disclosure.

FIG. 3 is a schematic diagram of a device for a dual in-line memory module in an embodiment of the present disclosure.

### DESCRIPTION OF REFERENCE NUMERALS

21 Position acquisition unit
22 Modification unit
23 Test unit
24 Storage unit
31 Processor
32 Memory

### DETAILED DESCRIPTION OF THE PREFERRED EMBODIMENTS

The embodiments of the present disclosure will be described below through exemplary embodiments. Those skilled in the art can easily understand other advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure. It needs to be stated that the following embodiments and the features in the embodiments can be combined with one another under the situation of no conflict.

It needs to be stated that the drawings provided in the following embodiments are just used for schematically describing the basic concept of the present disclosure, thus only illustrating components only related to the present disclosure and are not drawn according to the numbers, shapes and sizes of components during actual implementation, the configuration, number and scale of each component during the actual implementation thereof may be freely changed, and the component layout configuration thereof may be more complicated.

The test method, system, medium and device for a dual in-line memory module of the present disclosure is to prevent the server from being shut down during the test of the dual in-line memory module, and timely discover the defective dual in-line memory module.

Server manufacturers possess a tremendous amount of servers, therefore, testing the dual in-line memory modules of the server requires a lot of manpower and material resources. Operating System (OS) is a computer program that manages and controls computer hardware and software resources. OS is the most basic system software that runs directly on a “bare computer”. The operation of any other software must base on the support of OS. The DIMM test under OS is currently the most widely used DIMM test solution. Both the stress test used by a manufacturer and the DIMM test program used by a server administrator are the user mode program operated under OS. Testing DIMM under the OS has some inevitable disadvantages: 1. OS limits the memory capacity occupied by the processes for system stability. In the DIMM test program under the OS, the maximum DIMM capacity tested cannot exceed the maximum capacity occupied by the program that is allowed by OS. The DIMM test program is unable to cover all DIMMs. 2. The DIMM test program is subject to virtual addresses. The DIMM test program runs in a virtual address space, which only contains the user stack of the process and is unable to directly access the physical memory. This requires access to physical memory through system calls, which in turn increases system overhead. 3. When using memory, the OS does not use all DIMMs as memory. The DIMM test program is unable to test the memory occupied by the OS itself. In addition, a part of the memory is marked as only accessible by the system, and a part of the memory records some important data passed by the BIOS to the OS, such as advanced configuration and power interface (ACPI). This part of the DIMM is not allowed to be modified.

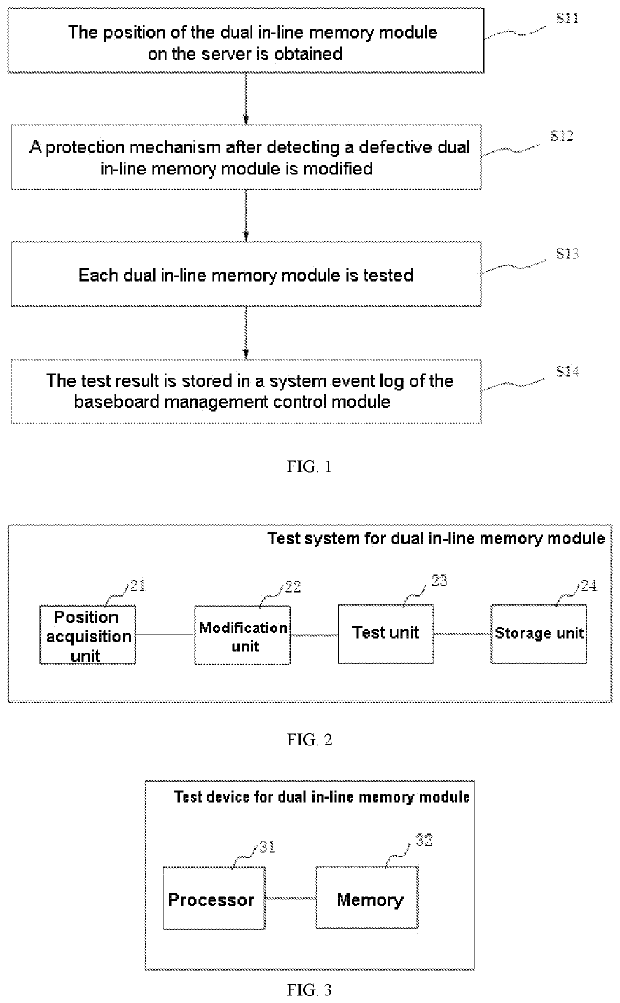

As shown in FIG. 1, in an embodiment, the test method for a dual in-line memory module of the present disclosure includes the following operations:

Specifically, pre-processing is included before all the operations. The pre-processing operation is booting using a preboot execute environment (PXE). PXE is the latest technology developed by Intel Corporation. PXE works in the Client/Server network mode, supports workstations to download images from remote servers via the network, and thus supports to boot an operating system via the network. During the boot, the terminal requires the server to allocate an IP address, and then uses trivial file transfer protocol (TFTP) or multicast trivial file transfer protocol (MTFTP) to download a boot software package to the local memory for execution. The basic software setting of the terminal (client-side) is completed by the boot software package, thereby booting the terminal operating system pre-installed in the server. PXE may boot a variety of operating systems. After the pre-processing, the BIOS DIMM test program can be entered. The pre-processing operation further includes preparing a data structure.

S11: the position of the dual in-line memory module on the server is obtained.

Specifically, the position refers to a specific slot position of the dual in-line memory module on the server. That is, the server has a slot for inserting the dual in-line memory module. Knowing the specific slot position of the dual in-line memory module on the server means obtaining the position of the dual in-line memory module on the server.

Specifically, the operation further includes recording whether each slot is available.

S12: a protection mechanism after detecting a defective dual in-line memory module is modified, the modification of the protection mechanism after detecting the defective dual in-line memory module includes: prohibiting the function of shutting down the server after detecting the defective dual in-line memory module; prohibiting the function that the memory reference code shuts down the server after detecting the defective dual in-line memory module; prohibiting the function that the basic input output module gets stuck in a loop after detecting the defective dual in-line memory module.

Specifically, the “defective” means that the dual in-line memory module has a problem and cannot work properly. In traditional technology, if the BIOS finds a problem with the DIMM while booting the computer, the computer would be shut down. Therefore, this function needs to be turned off in the BIOS, otherwise, the computer may be shut down by the BIOS after the test program finds a defective DIMM, which hinders the subsequent tests. The automation of processes is affected. In extreme cases, if the DIMM is of poor quality, an exception may occur in the BIOS itself. Even if the operating system (OS) is entered luckily, there would probably be a reboot or crash. Therefore, it is necessary to modify the protection mechanism after detecting a defective dual in-line memory module, which includes: prohibiting the function of shutting down the server after detecting the defective dual in-line memory module; prohibiting the function that the memory reference code shuts down the server after detecting the defective dual in-line memory module; prohibiting the function that the basic input output module gets stuck in a loop after detecting the defective dual in-line memory module. The prohibiting the function of shutting down the server after detecting the defective dual in-line memory module means that even if the dual in-line memory module is detected to be defective, the server would not be shut down immediately. The function that the memory reference code shuts down the server after detecting the defective dual in-line memory module refers to the function that the memory reference code (MRC) shuts down the server after detecting the defective dual in-line memory module. That is, even if the memory reference code detects the defective dual in-line memory module, the server would not be shut down immediately. The memory reference code is used to support the detection of a dual in-line memory module. The conventional memory reference code would shut down the server after detecting that the dual in-line memory module is defective. In the present disclosure, the function of shutting down the server after the memory reference code detects the defective dual in-line memory module is turned off. The prohibiting the function that the basic input output module gets stuck in a loop after detecting the defective dual in-line memory module means that even if a dual in-line memory module is detected to be defective, the basic input output module would not be rebooted. In conventional cases, when a dual in-line memory module is detected to be defective, the basic input output module will be rebooted, however, even if the basic input output module is rebooted, it will continue to detect whether the dual in-line memory module is defective, which causes the basic input output module to be stuck in a loop. In the present disclosure, the computer would not be shut down or rebooted due to the discovery of a few defective DIMMs, and the test is capable of covering all DIMMs.

S13: each dual in-line memory module is tested.

Specifically, the “testing” refers to detecting whether each dual in-line memory module can work properly. The test of the dual in-line memory module determines whether the dual in-line memory module is a defective dual in-line memory module by reading the associated registers of the programmable gain control register (CPGC) in the CPU.

S14: the test result is stored in a system event log of the baseboard management control module.

Specifically, in the traditional technology, the test results would pass through a unified extensible firmware interface (UEFI), which is a standard for describing types of interfaces in detail. Such type of interface is used to automatically load an operating system from a pre-boot operating environment to an operating system. Therefore, in the traditional technology, the test results are stored in the RAM through UEFI. Setting UEFI to be accessible under the OS and to be accessible during the BIOS boot process ensures that the test results can be updated at each boot. The disadvantage of this method is that it is only applicable to a UEFI boot, but not applicable to a Legacy boot (UEFI and Legacy are two different boot methods. UEFI is a new BIOS while Legacy is the traditional BIOS. The system installed in UEFI mode can only be booted in UEFI mode; similarly, the system installed in Legacy mode can only be entered in Legacy mode. UEFI only supports 64-bit systems and the disk partition must be in gpt mode. The traditional BIOS uses Int 13 to interrupt the reading of the disk, which can only read 64 KB at a time, which is very inefficient. UEFI can read 1 MB each time and load faster. In addition, Win8 has further optimized UEFI support, claiming that it can achieve instant boot).

Specifically, in the present disclosure, the test results are stored in a system event log (SEL) of the baseboard management control module. The test result stored in the system event log is obtained through a preset script. The preset script is an Intelligent Platform Management Interface (IMPI) platform management tool. The method is independent of how the operating system is booted. The disadvantage is that the capacity of SEL is limited, so it can't store too much information. Therefore, only the defective DIMM information is saved. The method requires support from hardware, and the server needs to have BMC function. The Baseboard Management Controller (BMC) is a device that is independent of the server baseboard and provides independent power. BMC provides a non-volatile memory chip for storing the SEL. Under the Linux system, IPMI can manage the BMC, by which the SEL can be obtained.

Specifically, the method further includes cleaning the system event log and burning the basic input output module. After the test of the dual in-line memory module is completed and before shipment, the system event log needs to be cleaned and the basic input output module needs to be burned, so as to ensure that there is no record of the test result in the server.

Specifically, the method further includes cleaning the SEL before each test of the dual in-line memory module to prevent previous records from affecting the test results. Before each test of the dual in-line memory module, the BIOS needs to be re-burned. Then, reboot the computer, and wait for the completion of the computer reboot. The purpose of re-burning the BIOS is to ensure that each test is conducted under the same conditions. The BIOS would be configured differently depending on whether the boot is the first, so the impact of the BIOS itself needs to be avoided. After the computer is rebooted, the BIOS DIMM test program is entered. After the test is completed, the BIOS would enter the operating system after finishing the work. By using ipmitool (the application of IPMI under Linux to manage the BMC, that is, the IMPI platform management tool) to obtain the SEL, the test results can be obtained automatically using a script without manual intervention.

As shown in FIG. 2, in an embodiment, the dual in-line memory module system of the present disclosure includes a position acquisition unit 21, a modification unit 22, a test unit 23, and a storage unit 24.

A pre-processing unit is further included for pre-processing.

Specifically, the pre-processing unit is booting using a preboot execute environment (PXE). PXE is the latest technology developed by Intel Corporation. PXE works in the Client/Server network mode, supports workstations to download images from remote servers via the network, and thus supports to boot an operating system via the network. During the boot, the terminal requires the server to allocate an IP address, and then uses trivial file transfer protocol (TFTP) or multicast trivial file transfer protocol (MTFTP) to download a boot software package to the local memory for execution. The basic software setting of the terminal (client-side) is completed by the boot software package, thereby booting the terminal operating system pre-installed in the server. PXE may boot a variety of operating systems. After the pre-processing, the BIOS DIMM test program can be entered. The pre-processing unit is also used to prepare a data structure.

The position acquisition unit 21 obtains the position of the dual in-line memory module on the server.

Specifically, the position refers to a specific slot position of the dual in-line memory module on the server. That is, the server has a slot for inserting the dual in-line memory module. Knowing the specific slot position of the dual in-line memory module on the server means obtaining the position of the dual in-line memory module on the server.

Specifically, the unit is further used to record whether each slot is available.

The modification unit 22 modifies a protection mechanism after detecting a defective dual in-line memory module, the modification of the protection mechanism after detecting the defective dual in-line memory module includes: prohibiting the function of shutting down the server after detecting the defective dual in-line memory module; prohibiting the function that the memory reference code shuts down the server after detecting the defective dual in-line memory module; prohibiting the function that the basic input output module gets stuck in a loop after detecting the defective dual in-line memory module.

Specifically, the “defective” means that the dual in-line memory module has a problem and cannot work properly. In traditional technology, if the BIOS finds a problem with the DIMM while booting the computer, the computer would be shut down. Therefore, this function needs to be turned off in the BIOS, otherwise, the computer may be shut down by the BIOS after the test program finds a defective DIMM, which hinders the subsequent tests. The automation of processes is affected. In extreme cases, if the DIMM is of poor quality, an exception may occur in the BIOS itself. Even if the OS is entered luckily, there would probably be a reboot or crash. Therefore, it is necessary to modify the protection mechanism after detecting a defective dual in-line memory module, which includes: prohibiting the function of shutting down the server after detecting the defective dual in-line memory module; prohibiting the function that the memory reference code shuts down the server after detecting the defective dual in-line memory module; prohibiting the function that the basic input output module gets stuck in a loop after detecting the defective dual in-line memory module. The prohibiting the function of shutting down the server after detecting the defective dual in-line memory module means that even if the dual in-line memory module is detected to be defective, the server would not be shut down immediately. The function that the memory reference code shuts down the server after detecting the defective dual in-line memory module refers to the function that the memory reference code (MRC) shuts down the server after detecting the defective dual in-line memory module. That is, even if the memory reference code detects the defective dual in-line memory module, the server would not be shut down immediately. The memory reference code is used to support the detection of a dual in-line memory module. The conventional memory reference code would shut down the server after detecting that the dual in-line memory module is defective. In the present disclosure, the function of shutting down the server after the memory reference code detects the defective dual in-line memory module is turned off. The prohibiting the function that the basic input output module gets stuck in a loop after detecting the defective dual in-line memory module means that even if a dual in-line memory module is detected to be defective, the basic input output module would not be rebooted. In conventional cases, when a dual in-line memory module is detected to be defective, the basic input output module will be rebooted, however, even if the basic input output module is rebooted, it will continue to detect whether the dual in-line memory module is defective, which causes the basic input output module to be stuck in a loop. In the present disclosure, the computer would not be shut down or rebooted due to the discovery of a few defective DIMMs, and the test is capable of covering all DIMMs.

The test unit 23 tests each dual in-line memory module.

Specifically, the “test” refers to detecting whether each dual in-line memory module can work properly. The test of the dual in-line memory module determines whether the dual in-line memory module is a defective dual in-line memory module by reading the associated registers of the CPGC in the CPU.

The storage unit 24 stores the test result in a system event log of the baseboard management control module.

Specifically, in the traditional technology, the test results would pass through a UEFI, which is a standard for describing types of interfaces in detail. Such type of interface is used to automatically load an operating system from a pre-boot operating environment to an operating system. Therefore, in the traditional technology, the test results are stored in the RAM through UEFI. Setting UEFI to be accessible under the OS and to be accessible during the BIOS boot process ensures that the test results can be updated at each boot. The disadvantage of this method is that it is only applicable to a UEFI boot, but not applicable to a Legacy boot (UEFI and Legacy are two different boot methods. UEFI is a new BIOS while Legacy is the traditional BIOS. The system installed in UEFI mode can only be booted in UEFI mode; similarly, the system installed in Legacy mode can only be entered in Legacy mode. UEFI only supports 64-bit systems and the disk partition must be in gpt mode. The traditional BIOS uses Int 13 to interrupt the reading of the disk, which can only read 64 KB at a time, which is very inefficient. UEFI can read 1 MB each time and load faster. In addition, Win8 has further optimized UEFI support, claiming that it can achieve instant boot.)

Specifically, in the present disclosure, the test results are stored in a system event log (SEL) of the baseboard management control module. The test result stored in the system event log is obtained through a preset script. The preset script is an IMPI platform management tool. The method is independent of how the operating system is booted. The disadvantage is that the capacity of SEL is limited, so it can't store too much information. Therefore, only the defective DIMM information is saved. The method requires support from hardware, and the server needs to have BMC function. The BMC is a device that is independent of the server baseboard and provides independent power. BMC provides a non-volatile memory chip for storing the SEL. Under the Linux system, IPMI can manage the BMC, by which the SEL can be obtained.

Specifically, the unit is further used to clean the system event log and burn the basic input output module. After the test of the dual in-line memory module is completed and before shipment, the system event log needs to be cleaned and the basic input output module needs to be burned, so as to ensure that there is no record of the test result in the server.

Specifically, the unit is further used to clean the SEL before each test of the dual in-line memory module to prevent previous records from affecting the test results. Before each test of the dual in-line memory module, the BIOS needs to be re-burned. Then, reboot the computer, and wait for the completion of the computer reboot. The purpose of re-burning the BIOS is to ensure that each test is conducted under the same conditions. The BIOS would be configured differently depending on whether the boot is the first, so the impact of the BIOS itself needs to be avoided. After the computer is rebooted, the BIOS DIMM test program is entered. After the test is completed, the BIOS would enter the operating system after finishing the work. By using ipmitool (the application of IPMI under Linux to manage the BMC, that is, the IMPI platform management tool) to obtain the SEL, the test results can be obtained automatically using a script without manual intervention.

It should be noted that the structure and principle of the position acquisition unit 21, modification unit 22, test unit 23, and storage unit 24 correspond to the operations in the above-mentioned test method of the dual in-line memory module one by one, and will not be described herein.

It should be noted that the division of each unit of the above system is only a division of logical functions. In actual implementation, the units may be integrated into one physical entity in whole or in part, or may be physically separated. And these units may all be implemented in the form of processing component calling by software, or they may all be implemented in the form of hardware. It is also possible that some units are implemented in the form of processing component calling by software, and some units are implemented in the form of hardware. For example, the x unit may be a separate processing component, or may be integrated into a chip of the above-mentioned apparatus, or may be stored in the memory of the above apparatus in the form of program code. The function of the above x unit is called and executed by one of the processing elements of the above apparatus. The implementation of other units is similar. In addition, all or part of these units may be integrated or implemented independently. The processing elements described herein may be an integrated circuit with signal processing capabilities. In the implementation process, each step of the above method or each of the above units may be completed by an integrated logic circuit of hardware in the processor component or an instruction in a form of software.

For example, the above units may be one or more integrated circuits configured to implement the above method, such as one or more Application Specific Integrated Circuits (ASICs), or one or more Digital Singnal Processors (DSPs), or one or more Field Programmable Gate Arrays (FPGAs). As another example, when one of the above units is implemented in the form of calling program codes of a processing component, the processing component may be a general processor, such as a Central Processing Unit (CPU) or other processors that may call program codes. As another example, these units may be integrated and implemented in the form of a system-on-a-chip (SOC).

As shown in FIG. 3, in an embodiment, the test device for a dual in-line memory module of the present disclosure includes a processor 31 and a memory 32; the memory 32 stores a computer program, and the processor 31 is connected to the memory 32 to execute the computer program stored in the memory, so that the test device for a dual in-line memory module implements any of the test methods for a dual in-line memory module described above.

Specifically, the memory 32 includes various mediums that may store program codes, such as a ROM, a RAM, a magnetic disk, a USB flash disk, a memory card, or an optical disk.

Preferably, the processor 31 may be a general processor, including a Central Processing Unit (CPU), a Network Processor (NP), etc; it may also be a Digital Signal Processor (DSP), Application Specific Integrated Circuit (ASIC), Field Programmable Gate Array (FPGA) or other programmable logic devices, discrete gate or transistor logic devices, discrete hardware components.

To sum up, the test method, system, medium and device for a dual in-line memory module of the present disclosure is to prevent the server from being shut down during the test of the dual in-line memory module, and timely detect the defective dual in-line memory module. Therefore, the present disclosure effectively overcomes various shortcomings in traditional technology and has high industrial utilization value.

The above-described embodiments are merely illustrative of the principles of the disclosure and its effects, and are not intended to limit the disclosure. Modifications or variations of the above-described embodiments may be made by those skilled in the art without departing from the spirit and scope of the disclosure. Therefore, all equivalent modifications or changes made by those who have common knowledge in the art without departing from the spirit and technical concept disclosed by the present disclosure shall be still covered by the claims of the present disclosure.

What is claimed is:

1. A test method for a dual in-line memory module, comprising:
obtaining a position of the dual in-line memory module on a server;
modifying a protection mechanism after detecting a defective dual in-line memory module, wherein the modifying a protection mechanism after detecting the defective dual in-line memory module includes: prohibiting a function of shutting down the server after detecting the defective dual in-line memory module; prohibiting a function that a memory reference code shuts down the server after detecting the defective dual in-line memory module; prohibiting a function that a basic input output module gets stuck in a loop after detecting the defective dual in-line memory module;
testing each dual in-line memory module;
storing a test result in a system event log of a baseboard management control module.

2. The test method for a dual in-line memory module according to claim 1, furthering comprising obtaining the test result stored in the system event log through a preset script.

3. The test method for a dual in-line memory module according to claim 2, wherein the preset script is an IMPI platform management tool.

4. The test method for a dual in-line memory module according to claim 1, further comprising cleaning the system event log and burning the basic input output module.

5. A test system for a dual in-line memory module, comprising a position acquisition unit, a modification unit, a test unit, and a storage unit;
the position acquisition unit obtains a position of the dual in-line memory module on a server;
the modification unit modifies a protection mechanism after detecting a defective dual in-line memory module, the modification of the protection mechanism after detecting the defective dual in-line memory module includes: prohibiting a function of shutting down the server after detecting the defective dual in-line memory module; prohibiting a function that a memory reference code shuts down the server after detecting the defective dual in-line memory module; prohibiting a function that a basic input output module gets stuck in a loop after detecting the defective dual in-line memory module;
the test unit tests each dual in-line memory module;
the storage unit stores a test result in a system event log of a baseboard management control module.

6. The test system for a dual in-line memory module according to claim 5, furthering comprising a result acquisition unit to obtain the test result stored in the system event log through a preset script.

7. The test system for a dual in-line memory module according to claim 6, wherein the preset script is an IMPI platform management tool.

8. The test system for a dual in-line memory module according to claim 5, further comprising a cleaning unit to clean the system event log and burn the basic input output module.

9. A test device for a dual in-line memory module, comprising a processor and a memory; the memory stores a computer program; the processor is connected with the memory to execute the computer program stored in the memory, such that the device implements the test method for a dual in-line memory module as described in claim 1.
